(19) United States
(12) Patent Application Publication
(10) Pub. No.: US 2023/0268342 A1
(43) Pub. Date: Aug. 24, 2023

(54) SEMICONDUCTOR DEVICE

(71) Applicant: FUJI ELECTRIC CO., LTD., Kanagawa (JP)

(72) Inventors: Yoshihiro IKURA, Matsumoto-city (JP); Seiji NOGUCHI, Matsumoto-city (JP); Yosuke SAKURAI, Azumino-city (JP); Ryutaro HAMASAKI, Matsumoto-city (JP)

(21) Appl. No.: 18/305,387

(22) Filed: Apr. 24, 2023

Related U.S. Application Data
(63) Continuation of application No. PCT/JP2021/045100, filed on Dec. 8, 2021.

(30) Foreign Application Priority Data
May 11, 2021 (JP) 2021-080620

(51) Int. Cl. H01L 27/06; H01L 29/06; H01L 29/10; H01L 29/861; H01L 29/739

(52) U.S. Cl. CPC H01L 27/0664; H01L 29/0623; H01L 29/1095; H01L 29/8613; H01L 29/7397

(57) ABSTRACT

Provided is a semiconductor device including an active section having a transistor section and a diode section, and an edge termination structure section provided to an outer circumference of the active section, in which the transistor section has a drift region of a first conductivity type which is provided in a semiconductor substrate, a base region of a second conductivity type which is provided above the drift region, a trench portion extending from a front surface of the semiconductor substrate to the drift region, and a trench bottom portion of the second conductivity type which is provided in a lower end of the trench portion, and the diode section is provided between a transistor section in proximity to the edge termination structure section, and the edge termination structure section in a top view.

The contents of the following Japanese patent application(s) are incorporated herein by reference:
NO. 2021-080620 filed in JP on May 11, 2021
NO. PCT/JP2021/045100 filed in WO on Dec. 8, 2021

### BACKGROUND

### 1. Technical Field

The present invention relates to a semiconductor device.

### 2. Related Art

Patent document 1 describes that at least a part of an IGBT cell includes an electrically floating barrier region of a second conductivity type.

### LIST OF CITED REFERENCES

### Patent Document

Patent Document 1: Japanese Patent Application Publication No. 2019-91892

### Problems to be Solved

When such a barrier region is in contact with a well region provided in a semiconductor substrate, a turn-on characteristic falls.

### BRIEF DESCRIPTION OF THE DRAWINGS

FIG. 1 illustrates an example of an upper surface of a semiconductor device 100 according to the present embodiment.

FIG. 2A is an enlarged view representing an example of the upper surface of the semiconductor device 100.

FIG. 2B illustrates a cross section a-a′ in FIG. 2A.

FIG. 2C illustrates a cross section b-b′ in FIG. 2A.

FIG. 2D illustrates a cross section c-c′ in FIG. 2A.

FIG. 2E illustrates a cross section d-d′ in FIG. 2A.

FIG. 2F illustrates another example of the cross section a-a′ in FIG. 2A.

FIG. 2G illustrates another example of the cross section a-a′ in FIG. 2A.

FIG. 3A is an enlarged view representing an example of an upper surface of a semiconductor device 200 according to a comparative example.

FIG. 3B illustrates a cross section e-e′ in FIG. 3A.

FIG. 4 is a graph representing breakdown voltage waveforms of the semiconductor device 100 and the semiconductor device 200.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as ‘upper’ or ‘front’ and the other side is referred to as ‘lower’ or ‘rear’. One surface of two principal surfaces of a substrate, a layer, or other member is referred to as a front surface, and the other surface is referred to as a back surface. “Upper” and “lower” directions are not limited to a direction of gravity, or a direction in which a semiconductor device is mounted.

As used herein, technical matters may be described with orthogonal coordinate axes consisting of an X axis, a Y axis, and a Z axis. The orthogonal coordinate axes are merely for specifying relative positions of components, and are thus not for limiting to a specific direction. For example, the Z axis is not limited to represent a height direction with respect to the ground. Note that a +Z axis direction and a −Z axis direction are directions opposite to each other. When a direction is referred to as a “Z axis direction” without these “+” and “−” signs, it means the Z axis direction is parallel to +Z and −Z axes.

In the present specification, orthogonal axes parallel to the front surface and the back surface of the semiconductor substrate are referred to as the X axis and the Y axis. In addition, an axis perpendicular to the front surface and the back surface of the semiconductor substrate is referred to as the Z axis. As used herein, a direction of the Z axis may be referred to as a depth direction. In addition, in the present specification, a direction parallel to the front surface and the back surface of the semiconductor substrate may be referred to as a horizontal direction, including an X axis direction and a Y axis direction.

As used herein, phrases such as “same” or “equal” may be used even when there is an error caused due to a variation in a fabrication step or the like. This error is within a range of 10% or less, for example.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor showing a conductivity type of the N type, or a semiconductor showing a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking polarities of charges into account. As an example, when the donor concentration is referred to as N_{D} and the acceptor concentration is referred to as N_{A}, the net doping concentration at any position is given as N_{D}-N_{A}.

The donor has a function of supplying electrons to a semiconductor. The acceptor has a function of receiving electrons from the semiconductor. The donor and acceptor are not limited to the impurities themselves. For example, a VOH defect which is a combination of a vacancy (V), oxygen (O), and hydrogen (H) existing in the semiconductor functions as the donor that supplies electrons.

A P+ type or an N+ type described in the present specification means a doping concentration higher than that of the P type or the N type, and a P− type or an N− type described herein means a doping concentration lower than that of the P type or the N type. Furthermore, a P++ type or an N++ type described in the present specification means a higher doping concentration than that of the P+ type or the N+ type.

A chemical concentration in the present specification refers to the concentration of impurities, which is measured regardless of the state of electrical activation. The chemical concentration can be measured by, for example, secondary ion mass spectrometry (SIMS). The net doping concentration described above can be measured by capacitance-voltage profiling method (CV method). Furthermore, a carrier concentration measured by a spreading resistance profiling method (SR method) may be set as the net doping concentration. The carrier concentration measured by the CV method or the SR method may be set as a value in a thermal equilibrium state. Furthermore, in a region of an N type, the donor concentration is sufficiently higher than the acceptor concentration, and therefore, the carrier concentration in the region may be set as the donor concentration. Similarly, in a region of a P type, the carrier concentration in the region may be set as the acceptor concentration.

Furthermore, when a concentration distribution of the donor, acceptor, or net doping has a peak, a value of the peak may be set as the concentration of the donor, acceptor, or net doping in the region. When the concentration of the donor, acceptor, or net doping is approximately uniform in a region, or the like, an average value of the concentration of the donor, acceptor, or net doping in the region may be set as the concentration of the donor, acceptor, or net doping.

The carrier concentration measured by the SR method may be lower than the concentration of the donor or the acceptor. In a range where a current flows when a spreading resistance is measured, the carrier mobility of the semiconductor substrate may be lower than a value of that in a crystalline state. The fall in carrier mobility occurs when carriers are scattered due to disorder (disorder) of a crystal structure due to a lattice defect or the like.

The concentration of the donor or the acceptor calculated from the carrier concentration measured by the CV method or the SR method may be lower than a chemical concentration of an element representing the donor or the acceptor. As an example, in a silicon semiconductor, a donor concentration of phosphorus or arsenic serving as a donor or an acceptor concentration of boron (boron) serving as an acceptor is substantially 99% of chemical concentrations of these. On the other hand, in the silicon semiconductor, a donor concentration of hydrogen serving as a donor is approximately 0.1% to 10% of a chemical concentration of hydrogen.

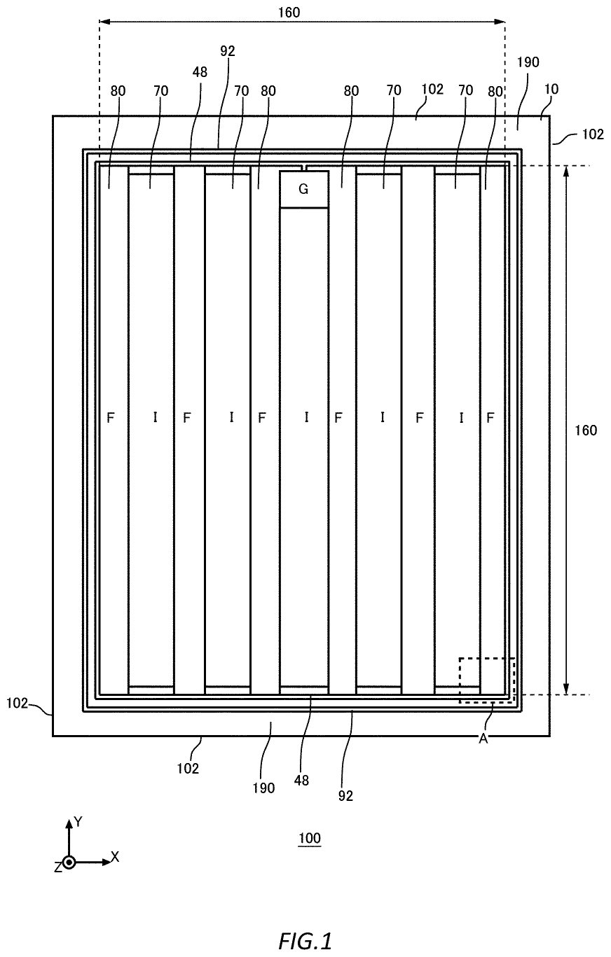

FIG. 1 illustrates an example of an upper surface of a semiconductor device 100 according to the present embodiment. FIG. 1 illustrates a position of each member as being projected onto a front surface of a semiconductor substrate 10. In FIG. 1, only some members of the semiconductor device 100 are illustrated, and illustrations of some members are omitted.

The semiconductor device 100 includes the semiconductor substrate 10. The semiconductor substrate 10 has an end side 102 in a top view. As simply used herein, unless otherwise specified, a top view means a view from the side of the front surface of the semiconductor substrate 10. The semiconductor substrate 10 of the present example includes two sets of end sides 102 facing each other in a top view. In FIG. 1, the X axis and the Y axis are parallel to any of end sides 102. In addition, the Z axis is perpendicular to the front surface of the semiconductor substrate 10.

The semiconductor substrate 10 is provided with an active section 160. The active section 160 is a region where a principal current flows in the depth direction between the front surface and the back surface of the semiconductor substrate 10 when the semiconductor device 100 operates. An emitter electrode is provided above the active section 160, but is omitted in FIG. 1.

The active section 160 is provided with at least one of a transistor section 70 including a transistor element such as an IGBT, or a diode section 80 including a diode element such as a free wheeling diode (FWD). In the example of FIG. 1, the transistor section 70 and the diode section 80 are alternately arranged along a predetermined array direction (X axis direction in the present example) in the front surface of the semiconductor substrate 10.

In FIG. 1, a region where each of the transistor sections 70 is arranged is represented by a symbol “I”, and a region where each of the diode sections 80 is arranged is represented by a symbol F. In the present specification, a direction perpendicular to the array direction in a top view may be referred to as an extension direction (the Y axis direction in FIG. 1). Each of the transistor sections 70 and the diode sections 80 may have a longitudinal length in the extension direction. In other words, the length of each of the transistor sections 70 in the Y axis direction is larger than the width in the X axis direction. Similarly, the length of each of the diode sections 80 in the Y axis direction is larger than the width in the X axis direction. The extension direction of the transistor section 70 and the diode section 80, and the longitudinal direction of each trench portion described below may be the same.

The transistor section 70 includes a collector region of a P+ type in a region in contact with the back surface of the semiconductor substrate 10. The diode section 80 has a cathode region of an N+ type in a region in contact with the back surface of the semiconductor substrate 10. In the present specification, a region where the collector region is provided is referred to as the transistor section 70. That is, the transistor section 70 is a region which overlaps the collector region in a top view.

A cathode region of an N+ type may be provided in a region other than the collector region to the back surface of the semiconductor substrate 10. In the present specification, a cathode region is provided to a lower surface of an extension region where the transistor section 70 extends in the Y axis direction up to a gate runner described below. In the present specification, the extension region is included in the diode section 80. Furthermore, in the transistor section 70, an emitter region of an N type, a base region of a P type, and a gate structure having a gate conductive portion and a gate dielectric film are periodically arranged on the front surface side of the semiconductor substrate 10.

The semiconductor device 100 may have one or more pads above the semiconductor substrate 10. As an example, the semiconductor device 100 illustrated in FIG. 1 has a gate pad G, which is, however, only an example. The semiconductor device 100 may have a pad such as an anode pad, a cathode pad, and a current detection pad. Each pad is arranged in the vicinity of the end side 102. The vicinity of the end side 102 refers to a region between the end side 102 and the emitter electrode in a top view. When the semiconductor device 100 is mounted, each pad may be connected to an external circuit via a wiring such as a wire.

A gate potential is applied to the gate pad G. The gate pad G is electrically connected to a conductive portion of a gate trench portion of the active section 160. The semiconductor device 100 includes a gate runner 48 configured to electrically connect the gate pad G and the gate trench portion.

The gate runner 48 is arranged between the active section 160 and the end side 102 of the semiconductor substrate 10 in a top view. The gate runner 48 of the present example surrounds the active section 160 in a top view. A region surrounded by the gate runner 48 in a top view may be set as the active section 160.

The gate runner 48 is arranged above the semiconductor substrate 10. The gate runner 48 of the present example may be formed of polysilicon doped with impurities, or the like. The gate runner 48 is electrically connected to the gate conductive portion provided inside the gate trench portion via a gate dielectric film.

The semiconductor device 100 in the present example includes an edge termination structure section 190 provided to an outer circumference of the active section 160. The edge termination structure section 190 of the present example is arranged between the gate runner 48 and the end side 102. The edge termination structure section 190 mitigates electric field strength on the front surface side of the semiconductor substrate 10.

The edge termination structure section 190 may have a guard ring 92. The guard ring 92 is a region of a P type in contact with the front surface of the semiconductor substrate 10. Note that the edge termination structure section 190 of the present example has a plurality of guard rings 92, which are omitted in FIG. 1, but only the single guard ring 92 is illustrated. By providing the plurality of guard rings 92, the depletion layer on the upper surface side of the active section 160 can be extended outward, and a breakdown voltage of the semiconductor device 100 can be improved. The edge termination structure section 190 may further include at least one of a field plate annularly provided to surround the active section 160 or a resurf.

Furthermore, the semiconductor device 100 may include a temperature sensing unit (not illustrated) that is a PN junction diode formed of polysilicon or the like, and a current detection unit (not illustrated) configured to simulate an operation of the transistor section provided in the active section 160.

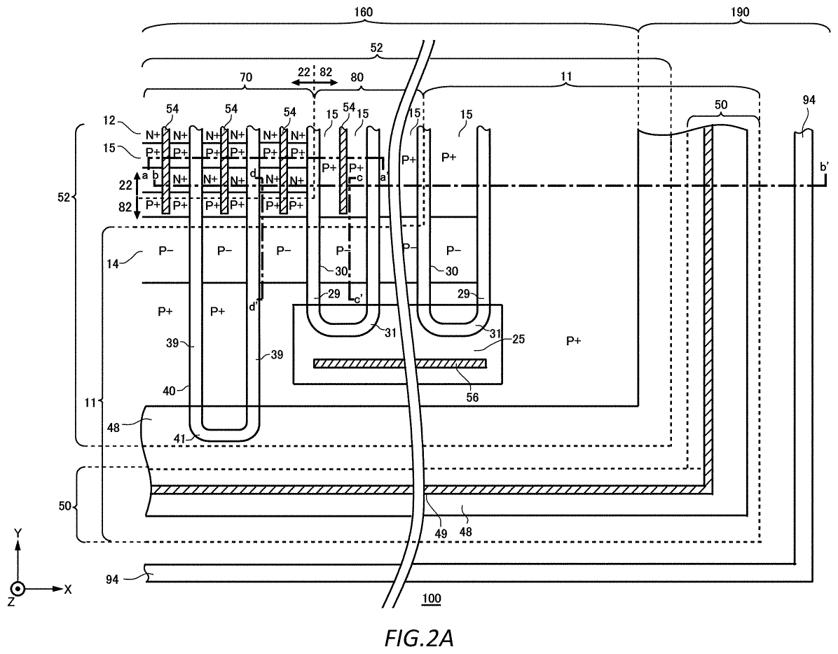

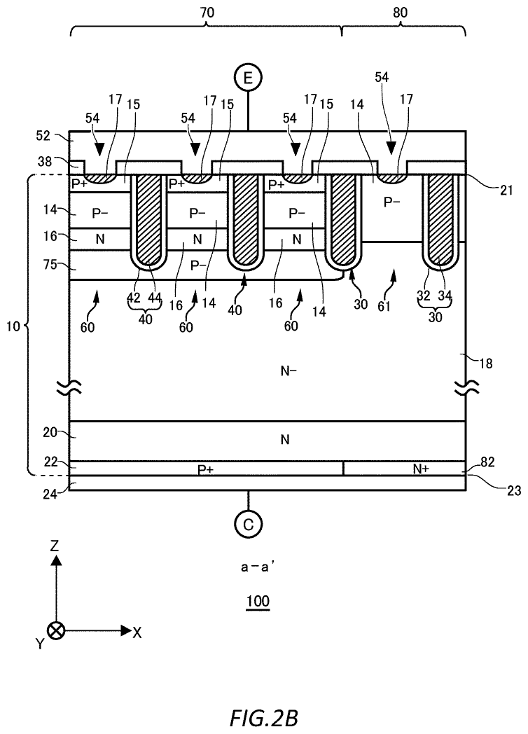

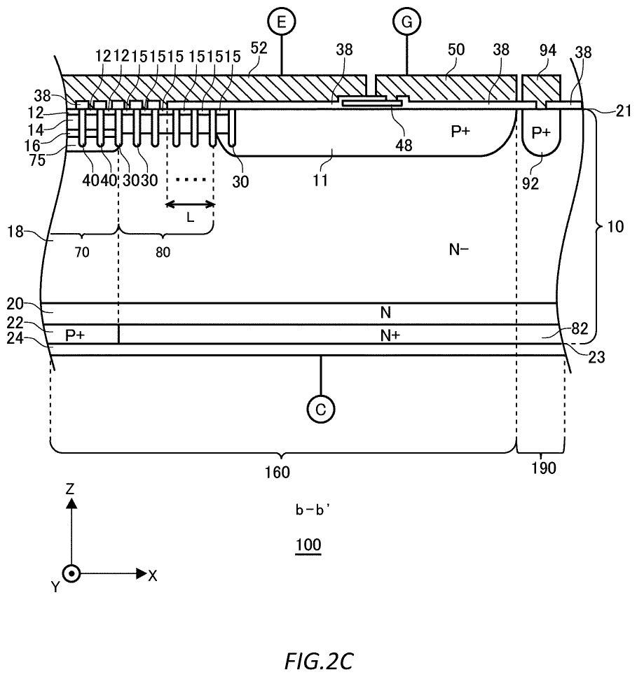

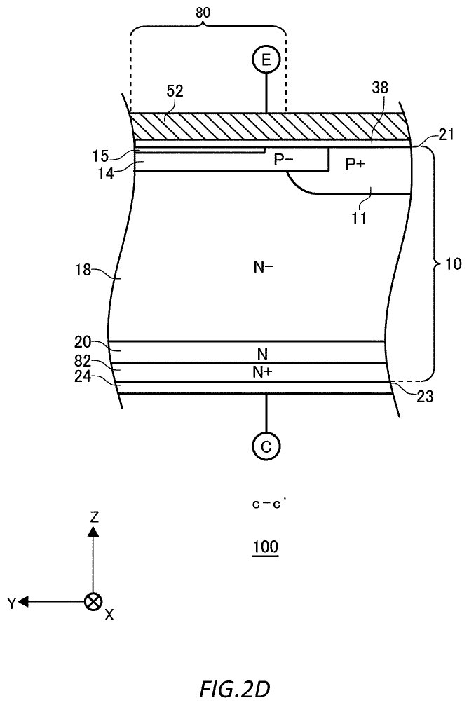

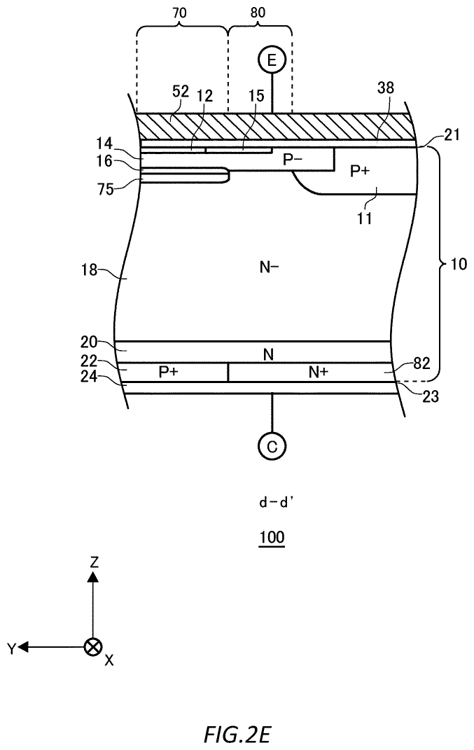

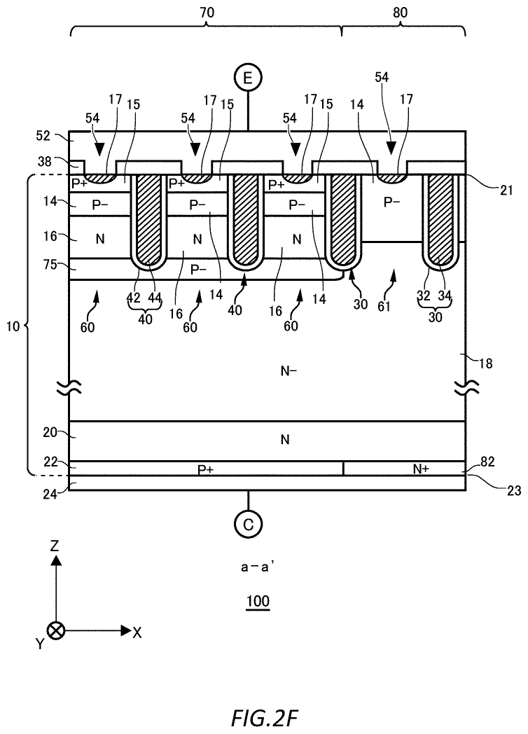

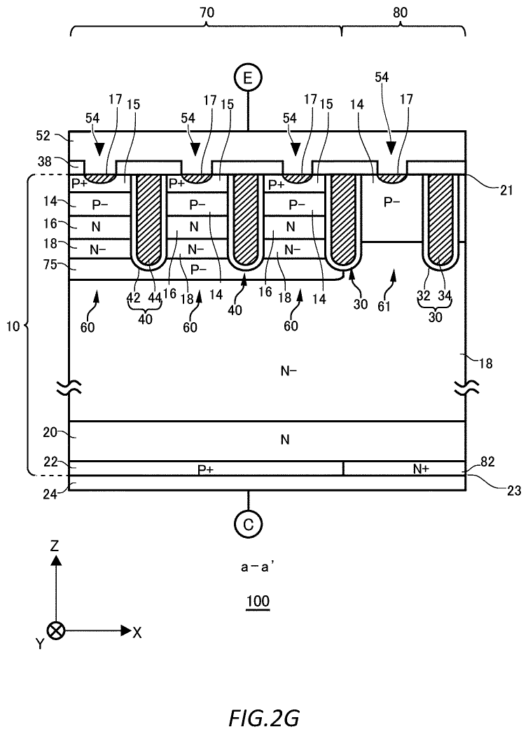

FIG. 2A is an enlarged view representing an example of the upper surface of the semiconductor device 100. FIG. 2A illustrates a region A illustrated in FIG. 1, that is, a vicinity of the boundary between the active section 160 and the edge termination structure section 190. The semiconductor device 100 is provided with the semiconductor substrate having the transistor section 70 including a transistor element such as an IGBT and the diode section 80 including a diode element such as a free wheeling diode (FWD).

The transistor section 70 and the diode section 80 of the present example are alternately arranged along the array direction (X axis direction in the present example). The diode section 80 is provided between the transistor section 70 in proximity to the edge termination structure section 190, and the edge termination structure section 190 in a top view. That is, the diode section 80 is arranged on an outermost side of the active section 160. Note that when terms “inner” and “outer” are simply used in the present specification, a direction towards a center of the semiconductor device 100 refers to inner, and a direction away from the center refers to outer.

The semiconductor device 100 of the present example includes a gate trench portion 40, a dummy trench portion 30, a well region 11, an emitter region 12, a base region 14, and a contact region 15 which are provided on the front surface side of the semiconductor substrate. The gate trench portion 40 and the dummy trench portion 30 each are an example of the trench portion.

In addition, the semiconductor device 100 in the present example includes a gate metal layer 50 and an emitter electrode 52 which are provided above the front surface of the semiconductor substrate. The gate metal layer 50 and the emitter electrode 52 are provided to be separated from each other. The gate metal layer 50 and the emitter electrode 52 are electrically insulated.

An interlayer dielectric film is provided between the emitter electrode 52 and the gate metal layer 50 and the front surface of the semiconductor substrate, but is omitted in FIG. 2A. In the interlayer dielectric film of the present example, contact holes 49, 54, and 56 are provided penetrating through the interlayer dielectric film. In FIG. 2A, each contact hole is hatched with oblique lines.

The emitter electrode 52 is provided above the gate trench portion 40, the dummy trench portion 30, the well region 11, the emitter region 12, the base region 14, and the contact region 15. The emitter electrode 52 is electrically connected to the emitter region 12, the base region 14, and the contact region 15 for the front surface of the semiconductor substrate through the contact hole 54.

In addition, the emitter electrode 52 is connected to a dummy conductive portion in the dummy trench portion 30 by the contact hole 56. A connection portion 25 formed of a conductive material such as polysilicon doped with impurities may be provided between the emitter electrode 52 and the dummy conductive portion. The connection portion 25 is provided to the front surface of the semiconductor substrate via a dielectric film such as an interlayer dielectric film and a dummy dielectric film of the dummy trench portion 30.

The gate metal layer 50 is electrically connected to the gate runner 48 through the contact hole 49. The gate runner 48 may be formed of polysilicon doped with impurities, or the like. The gate runner 48 is connected to a gate conductive portion in the gate trench portion 40 in the front surface of the semiconductor substrate. The gate runner 48 is not electrically connected to the dummy conductive portion in the dummy trench portion 30 and the emitter electrode 52.

The gate runner 48 and the emitter electrode 52 are electrically separated by an insulating material such as an interlayer dielectric film and an oxide film. The gate runner 48 of the present example is provided from a position below the contact hole 49 to edge portions of the gate trench portions 40. At the edge portion of the gate trench portion 40, the gate conductive portion is exposed at the front surface of the semiconductor substrate to be connected to the gate runner 48.

The emitter electrode 52 and the gate metal layer 50 are formed of a conductive material containing metal. For example, the emitter electrode and the gate metal layer are formed of an alloy containing aluminum or aluminum as a main component (for example, an aluminum-silicon alloy or the like). Each electrode may have a barrier metal formed of titanium, a titanium compound, or the like as an underlying layer of a region formed of aluminum or the like.

Each electrode may have a plug formed of tungsten or the like in the contact hole. The plug may have a barrier metal on a side in contact with the semiconductor substrate and have tungsten embedded to be in contact with the barrier metal, and may be formed of aluminum or the like on tungsten.

Note that the plug is provided in the contact hole in contact with the contact region 15 or the base region 14. In addition, a plug region of a P++ type is formed under the contact hole of the plug, and has a doping concentration higher than that of the contact region 15. This can improve a contact resistance between the barrier metal and the contact region 15. Furthermore, a depth of the plug region is about 0.1 μm or less, and has a small region with a depth that is 10% or less of that of the contact region 15.

A plug region has following features. In an operation of the transistor section 70, a latch-up resistance is improved by improvement on the contact resistance. On the other hand, in an operation of the diode section 80, when the plug region dose not exist, a contact resistance between the barrier metal and the base region 14 is high, and a conduction loss and a switching loss rise. However, with the provision of the plug region, the rise in the conduction loss and the switching loss can be suppressed.

The well region 11 overlaps the gate runner 48 to extend in the outer circumference of the active section 160, and is annularly provided in a top view. The well region 11 extends in a predetermined width even in a range without overlapping the gate runner 48, and is annularly provided in a top view. The well region 11 of the present example is provided away from the end of the contact hole 54 in the Y axis direction towards the gate runner 48. The well region 11 is a region of a second conductivity type in which the doping concentration is higher than the base region 14. The gate runner 48 is electrically insulated from the well region 11.

The base region 14 of the present example is a P− type, and the well region 11 is a P+ type. In addition, the well region 11 is formed from the front surface of the semiconductor substrate to a position deeper than a lower end of the base region 14. The base region 14 is provided in contact with the well region 11 in the transistor section 70 and the diode section 80. Therefore, the well region 11 is electrically connected to the emitter electrode 52.

Each of the transistor section 70 and the diode section 80 includes a plurality of trench portions arranged in the array direction. In the transistor section 70 of the present example, one or more gate trench portions 40 are provided along the array direction. In the diode section 80 of the present example, the plurality of dummy trench portions 30 are provided along the array direction. In the diode section 80 of the present example, the gate trench portion 40 is not provided.

The gate trench portion 40 of the present example may have two linear segments 39 extending along the extension direction perpendicular to the array direction (portions of a trench that are linear along the extension direction), and the edge portion 41 connecting the two linear segments 39.

At least a part of the edge portion 41 may be provided in a curved shape in a top view. The edge portion 41 connects the end portions of the two linear segments 39 in the Y axis direction to the gate runner 48, which functions as a gate electrode to the gate trench portion 40. On the other hand, by forming the edge portion 41 into a curved shape, electric field strength at the end portions can be further reduced as compared with a case where the gate trench portion is completed with the linear segments 39.

In another example, one or more gate trench portions 40 and one or more dummy trench portions 30 may be alternately provided along the array direction in the transistor section 70. In the transistor section 70, the dummy trench portion 30 is provided between the respective linear segments 39 of the gate trench portion 40. Between the respective linear segments 39, one dummy trench portion 30 may be provided, or a plurality of dummy trench portions 30 may be provided.

The dummy trench portion 30 may not be provided between the respective linear segments 39, and the gate trench portion 40 may be provided therebetween. With such a structure, the electron current from the emitter region 12 can be increased, so that an ON voltage is reduced.

The dummy trench portion 30 may have a linear shape extending in the extension direction, and may have linear segments 29 and an edge portion 31, similar to the gate trench portion 40. In the semiconductor device 100 illustrated in FIG. 2A, only the dummy trench portions 30 having the edge portions 31 are arrayed. However, in another example, the semiconductor device 100 may include the linear dummy trench portion 30 without the edge portion 31.

A diffusion depth of the well region 11 may be deeper than the depth of the gate trench portion 40 and the dummy trench portion 30. The end portions in the Y axis direction of the gate trench portion 40 and the dummy trench portion 30 are provided in the well region 11 in a top view. In other words, the bottom in the depth direction of each trench portion is covered with the well region 11 at the end portion in the Y axis direction of each trench portion. In addition, the trench portion provided at the end portion in the X axis direction may be covered with the well region 11. With this configuration, the electric field strength in the bottom of each trench portion can be reduced.

A mesa portion is provided between the respective trench portions in the array direction. The mesa portion refers to a region sandwiched between the trench portions inside the semiconductor substrate. As an example, a depth position of the mesa portion is from the front surface of the semiconductor substrate to a lower end of the trench portion.

The mesa portion of the present example is sandwiched between the adjacent trench portions in the X axis direction, and is provided extending in the extension direction (Y axis direction) along the trench in the front surface of the semiconductor substrate. As will be described below with reference to FIG. 2B, in the present example, the transistor section 70 is provided with a mesa portion 60, and the diode section 80 is provided with a mesa portion 61. As simply used herein, unless otherwise specified, “mesa portion” refers to each of the mesa portion 60 and the mesa portion 61.

Each mesa portion is provided with the base region 14. In each mesa portion, at least one of the emitter region 12 of the first conductivity type or the contact region 15 of the second conductivity type may be provided in a region sandwiched between the base regions 14 in a top view. The emitter region 12 of the present example is an N+ type, and the contact region 15 is a P+ type. The emitter region 12 and the contact region 15 may be provided between the base region 14 and the front surface of the semiconductor substrate in the depth direction.

The mesa portion of the transistor section 70 has an emitter region 12 exposed at the front surface of the semiconductor substrate. The emitter region 12 is provided in contact with the gate trench portion 40. The mesa portion in contact with the gate trench portion 40 is provided with the contact region 15 exposed at the front surface of the semiconductor substrate.

Each of the contact region 15 and the emitter region 12 in the mesa portion is provided from one trench portion to the other trench portion in the X axis direction. As an example, the contact region 15 and the emitter region 12 in the mesa portion are alternately arranged along the extension direction of the trench portion (the Y axis direction).

In another example, the contact region 15 and the emitter region 12 in the mesa portion may be provided in a stripe shape along the extension direction of the trench portion (the Y axis direction). For example, the emitter region 12 is provided in a region in contact with the trench portion, and the contact region 15 is provided in a region sandwiched between the emitter regions 12.

The emitter region 12 is not provided in the mesa portion of the diode section 80. An upper surface of the mesa portion of the diode section 80 may be provided with the base region 14. The base region 14 may be arranged in the entire mesa portion of the diode section 80.

The contact hole 54 is provided above each mesa portion. The contact hole 54 is arranged in a region sandwiched between the base regions 14 in its extension direction (Y axis direction). The contact hole 54 of the present example is provided above each region of the contact region 15, the base region 14, and the emitter region 12. The contact hole 54 may be arranged at the center of the mesa portion in the array direction (the X axis direction).

In the diode section 80, a region adjacent to the back surface of the semiconductor substrate is provided with a cathode region 82 of an N+ type. In the back surface of the semiconductor substrate, a region in which the cathode region 82 is not provided may be provided with a collector region 22 of a P+ type. In FIG. 2A, a boundary between the cathode region 82 and the collector region 22 is represented by a dotted line. In the edge termination structure section 190 too, the cathode region 82 of an N+ type may be provided on the back surface side of the semiconductor substrate.

FIG. 2B illustrates a cross section a-a′ in FIG. 2A. The cross section a-a′ is an XZ plane passing through the contact region 15 and the base region 14, and also through the gate trench portion 40 and the dummy trench portion 30. The semiconductor device 100 in the present example has the semiconductor substrate 10, an interlayer dielectric film 38, the emitter electrode 52, and the collector electrode 24 on the cross section a-a′.

The interlayer dielectric film 38 is provided to a front surface 21 of the semiconductor substrate 10. The interlayer dielectric film 38 is a dielectric film such as silicate glass added with impurities of, for example, boron, phosphorus, or the like. The interlayer dielectric film 38 may be in contact with the front surface 21, and another film such as an oxide film may be provided between the interlayer dielectric film 38 and the front surface 21. The interlayer dielectric film 38 is provided with the contact hole 54 described with reference to FIG. 2A.

The emitter electrode 52 is provided to the front surface 21 of the semiconductor substrate 10 and an upper surface of the interlayer dielectric film 38. The emitter electrode 52 is electrically connected to the front surface 21 through the contact hole 54 of the interlayer dielectric film 38. The plug region 17 of tungsten (W) or the like may be provided inside the contact hole 54. The collector electrode 24 is provided to a back surface 23 of the semiconductor substrate 10. The emitter electrode 52 and the collector electrode 24 are formed of a material including metal or a laminated film thereof.

The semiconductor substrate 10 may be a silicon substrate, may be a silicon carbide substrate, or may be a nitride semiconductor substrate such as gallium nitride, or the like. In the present example, the semiconductor substrate 10 is a silicon substrate.

The semiconductor substrate 10 has a drift region 18 of a first conductivity type. The drift region 18 of the present example is of an N− type. The drift region 18 may be a remaining region in the semiconductor substrate 10 in which the other doping regions have not been provided.

In the transistor section 70, one or more accumulation regions 16 may be provided above the drift region 18 in the Z axis direction. The accumulation region 16 is a region where the same dopant as that of the drift region 18 is accumulated at a higher concentration than the drift region 18. The doping concentration of the accumulation region 16 is higher than the doping concentration of the drift region 18.

The accumulation region 16 of the present example is an N type. The accumulation region 16 may be provided between the base region 14 and a trench bottom portion 75 which will be described below in the transistor section 70. The accumulation region 16 may be provided only in the transistor section 70, or may be provided in both the transistor section 70 and the diode section 80. With the provision of the accumulation region 16, it is possible to increase an injection enhancement effect (IE effect) of the carrier so as to lower the ON voltage.

In the transistor section 70, the emitter region 12 is provided in contact with the front surface 21 above the base region 14. The emitter region 12 is provided in contact with the gate trench portion 40. The doping concentration of the emitter region 12 is higher than the doping concentration of the drift region 18. Examples of the dopant of the emitter region 12 include arsenic (As), phosphorus (P), antimony (Sb), and the like.

The diode section 80 is provided with the base region 14 exposed at the front surface 21. The base region 14 of the diode section 80 operates as an anode.

The buffer region 20 of a first conductivity type may be provided below the drift region 18. The buffer region 20 of the present example is an N type. The doping concentration of the buffer region 20 is higher than the doping concentration of the drift region 18. The buffer region 20 may function as a field stopper layer configured to prevent a depletion layer expanding from a lower surface side of the base region 14 from reaching the collector region 22 and the cathode region 82.

In the transistor section 70, the collector region 22 is provided below the buffer region 20. The collector region 22 may be provided in contact with the cathode region 82 in the back surface 23.

In the diode section 80, the cathode region 82 is provided below the buffer region 20. The cathode region 82 may be provided at the same depth of that of the collector region 22 of the transistor section 70. The diode section 80 may function as a free wheeling diode (FWD) which allows the free wheeling current to flow in the reverse direction when the transistor section 70 is turned off.

The semiconductor substrate portion 10 is provided with the gate trench portion 40 and the dummy trench portion 30. The gate trench portion 40 and the dummy trench portion 30 are provided so as to penetrate the base region 14 and the accumulation region 16 from the front surface 21 and reach the drift region 18. The configuration of the trench portion penetrating the doping region is not limited to that fabricated in the order of forming the doping region and then forming the trench portion. The configuration of the trench portion penetrating the doping region also includes a configuration of the doping region being formed between the trench portions after forming the trench portion.

The gate trench portion 40 includes a gate trench provided in the front surface 21, a gate dielectric film 42, and a gate conductive portion 44. The gate dielectric film 42 is provided to cover the inner wall of the gate trench. The gate dielectric film 42 may be formed of an oxide film or a nitride film. The gate conductive portion 44 is provided to embed an inner side relative to the gate dielectric film 42 inside the gate trench. An upper surface of the gate conductive portion 44 may be in the same XY plane as the front surface 21. The gate dielectric film 42 insulates the gate conductive portion 44 from the semiconductor substrate 10. The gate conductive portion 44 is formed of polysilicon doped with impurities, or the like.

The gate conductive portion 44 may be provided to be longer than the base region 14 in the depth direction. The gate trench portion 40 is covered by the interlayer dielectric film 38 for the front surface 21. When a predetermined voltage is applied to the gate conductive portion 44, a channel is formed to a surface layer being at a boundary within the base region 14 and in direct contact with the gate trench, due to an electron inversion layer.

The dummy trench portion 30 may have the same structure as the gate trench portion 40 in the XZ cross section. The dummy trench portion 30 includes a dummy trench provided in the front surface 21, a dummy dielectric film 32, and a dummy conductive portion 34. The dummy dielectric film 32 is provided to cover an inner wall of the dummy trench. The dummy dielectric film 32 may be formed of an oxide film or a nitride film. The dummy conductive portion 34 is provided to embed an inner side relative to the dummy dielectric film 32 inside the dummy trench. The upper surface of the dummy conductive portion 34 may be in the same XY plane as the front surface 21. The dummy dielectric film 32 insulates the dummy conductive portion 34 from the semiconductor substrate 10. The dummy conductive portion 34 may be formed of the same material as the gate conductive portion 44.

In the present example, the gate trench portion 40 and the dummy trench portion 30 are covered by the interlayer dielectric film 38 for the front surface 21. It is noted that the bottoms of the dummy trench portion 30 and the gate trench portion 40 may be formed in a curved-surface shape (a curved-line shape in the cross section) convexly downward.

The transistor section 70 has the trench bottom portion 75 of a P type which is provided in the lower end of the trench portion. The trench bottom portion 75 of the present example is provided below the accumulation region 16. In the depth direction of the semiconductor substrate 10, the lower end of the trench bottom portion 75 may be positioned below the bottom of the gate trench portion 40. In other words, the trench bottom portion 75 may cover the bottom of the gate trench portion 40.

A doping concentration of the trench bottom portion 75 is larger than the doping concentration of the drift region 18, and is smaller than the doping concentration of the base region 14. The doping concentration of the trench bottom portion 75 is 1E12 cm⁻³ or more and 1E13 cm⁻³ or less.

In FIG. 2B, an end on the positive side in the X axis direction (diode section 80 side) of the trench bottom portion 75 matches the boundary between the cathode region 82 and the collector region 22, but may extend on the diode section 80 side relative to this, or may be positioned back in the transistor section 70.

The trench bottom portion 75 may be a floating layer which is electrically floating. In the present specification, the floating layer refers to a layer which is not electrically connected to any of electrodes such as the emitter electrode 52. With the provision of the trench bottom portion 75, the turn-on characteristic of the transistor section 70 is improved. In addition, with the provision of the trench bottom portion 75, the electric field strength in the bottom of the gate trench portion 40 is relaxed, and the avalanche capability is improved.

FIG. 2C is a cross sectional view illustrating a cross section b-b′ in FIG. 2A. The cross section b-b′ is an XZ plane passing through the emitter region 12, the contact region 15, and the base region 14, and also through the gate trench portion 40 and the dummy trench portion 30 in the vicinity of the boundary between the active section 160 and the edge termination structure section 190.

The diode section 80 of the present example is provided between the transistor section 70 in proximity to the edge termination structure section 190, and the edge termination structure section 190 in a top view. That is, the diode section 80 is arranged in a region in the active section 160 that is the closest to the edge termination structure section 190.

As described above, the transistor section 70 of the present example has the trench bottom portion 75. When the transistor section 70 is provided on the outermost side of the active section 160, the trench bottom portion 75 is not provided in a part of the transistor section 70, and the trench bottom portion 75 needs to be spaced apart from the well region 11 which is electrically connected to the emitter electrode 52. For example, when the trench bottom portion 75 is not provided in a certain range from the end on the edge termination structure section 190 side in the transistor section 70, the turn-on characteristic falls according to a decreased amount of the trench bottom portion 75.

In the present example, with the arrangement of the diode section 80 on the outermost side of the active section 160, since the trench bottom portion 75 can be provided in the entire transistor section 70, the turn-on characteristic can be improved.

In addition, with the provision of the trench bottom portion 75 in the entire transistor section 70, a breakdown voltage of the transistor section 70 is improved. With this configuration, the breakdown voltage of the entire semiconductor device 100 is improved, and the latch-up resistance is improved.

In the diode section 80 of the present example, the well region 11 is spaced apart from the emitter electrode 52. In the present example, with the provision of the interlayer dielectric film 38 between the well region 11 and the emitter electrode 52, the well region 11 can be insulated from the emitter electrode 52.

In a top view, the interlayer dielectric film 38 extends over a part of the diode section 80 provided on the outermost side of the active section 160 from the edge termination structure section 190. In FIG. 2C, a distance L between the end of the interlayer dielectric film 38 and the end of the well region 11 may be 10 μm or more and 30 μm or less.

Current crowding is likely to occur in the end of the well region 11 at the time of reverse recovery of the semiconductor device 100. In view of the above, a contact with the emitter electrode 52 in the diode section 80 is spaced apart from the end of the well region 11, so that reverse recovery resistance can be improved.

The transistor section 70 has the accumulation region 16 of an N type between the base region 14 and the trench bottom portion 75. The accumulation region 16 may be provided only in the transistor section 70, and may not be provided in the diode section 80.

Alternatively, the accumulation region 16 may be provided in both the transistor section 70 and the diode section 80. With the provision of the accumulation region 16, it is possible to increase the injection enhancement effect (IE effect) of the carrier so as to lower the ON voltage.

In the edge termination structure section 190, the cathode region 82 of an N type may be provided on the back surface 23 side of the semiconductor substrate 10. That is, the cathode region 82 may be continuously provided so as to surround the outer circumference of the active section 160 on the back surface 23 side of the semiconductor substrate 10 over the edge termination structure section 190 from the diode section 80.

FIG. 2D illustrates a cross section c-c′ in FIG. 2A. The cross section c-c′ is a YZ plane passing through the base region 14 and the contact region 15 which are provided in the diode section 80 in the vicinity of the end on the negative side in the Y axis direction of the active section 160.

In the present example, the diode section 80 is provided on the outermost side of the active section 160. In the diode section 80, the contact region 15 is provided to the front surface 21 of the semiconductor substrate 10. In addition, in the diode section 80, the base region 14 is exposed at the front surface 21 of the semiconductor substrate 10 on the outer side in the Y axis direction of the contact region 15. That is, in a top view, in the diode section 80, the contact region 15 is sandwiched by the base regions 14 in the Y axis direction.

The well region 11 is provided in the vicinity of the end on the negative side in the Y axis direction of the active section 160. The diffusion depth of the well region 11 is deeper than that of the base region 14. The well region 11 may extend in the Y axis direction to partially cover the bottom of the base region 14.

FIG. 2E illustrates a cross section d-d′ in FIG. 2A. The cross section d-d′ is a YZ plane passing through the emitter region 12, the base region 14, and the contact region 15 which are provided in the transistor section 70 in the vicinity of the end on the negative side in the Y axis direction of the active section 160. In addition, the cross section d-d′ passes through the extension region where the transistor section 70 is extended in the Y axis direction. A cathode region is provided to a lower surface of the extension region. That is, in a top view, the transistor section 70 is sandwiched by the diode sections 80 in the Y axis direction.

In the transistor section 70, the emitter region 12 and the contact region 15 are provided to the front surface 21 of the semiconductor substrate 10. In addition, in the transistor section 70, the base region 14 is exposed at the front surface 21 of the semiconductor substrate 10 on the outer side in the Y axis direction of the contact region 15. That is, in a top view, in the transistor section 70, the emitter region 12 and the contact region 15 are sandwiched by the base regions 14 in the Y axis direction.

In the transistor section 70, the accumulation region 16 and the trench bottom portion 75 are provided above the drift region 18. The trench bottom portion 75 is provided below the accumulation region 16. The trench bottom portion 75 may be provided in contact with a lower surface of the accumulation region 16.

FIG. 2F illustrates another example of the cross section a-a′ in FIG. 2A. Similarly as in FIG. 2B, the cross section a-a′ is an XZ plane passing through the contact region 15 and the base region 14, and also through the gate trench portion 40 and the dummy trench portion 30. The semiconductor device 100 in the present example has the semiconductor substrate 10, the interlayer dielectric film 38, the emitter electrode 52, and the collector electrode 24 on the cross section a-a′.

The trench bottom portion 75 provided to the lower end of the trench portion of the transistor section 70 is different from FIG. 2B as being thinner than the accumulation region 16 in the depth direction of the semiconductor substrate 10.

The lower end of the trench bottom portion 75 of the present example is positioned below the bottom of the gate trench portion 40 to cover the bottom of the gate trench portion 40. The trench bottom portion 75 may be a floating layer which is electrically floating.

In FIG. 2F, the end on the positive side in the X axis direction (diode section 80 side) of the trench bottom portion 75 matches the boundary between the cathode region 82 and the collector region 22, but may extend on the diode section 80 side relative to this, or may be positioned back in the transistor section 70. In the present example, an effect similar to FIG. 2B can be attained.

FIG. 2G illustrates another example of the cross section a-a′ in FIG. 2A. The cross section a-a′ is an XZ plane passing through the contact region 15 and the base region 14, and also through the gate trench portion 40 and the dummy trench portion 30 similarly as in FIG. 2B. The semiconductor device 100 in the present example has the semiconductor substrate 10, the interlayer dielectric film 38, the emitter electrode 52, and the collector electrode 24 on the cross section a-a′.

The trench bottom portion 75 is different from FIG. 2B and FIG. 2F in that the trench bottom portion is spaced apart from the accumulation region 16, that is, provided to have the intermediation of the drift region 18 between the accumulation region 16 and the trench bottom portion 75.

In the depth direction of the semiconductor substrate 10, the trench bottom portion 75 may be thinner than the accumulation region 16 or the drift region 18 between the accumulation region 16 and the trench bottom portion 75.

In FIG. 2G, the end on the positive side in the X axis direction (diode section 80 side) of the trench bottom portion 75 matches the boundary between the cathode region 82 and the collector region 22, but may extend on the diode section 80 side relative to this, or may be positioned back in the transistor section 70. In the present example, an effect similar to FIG. 2B can be attained.

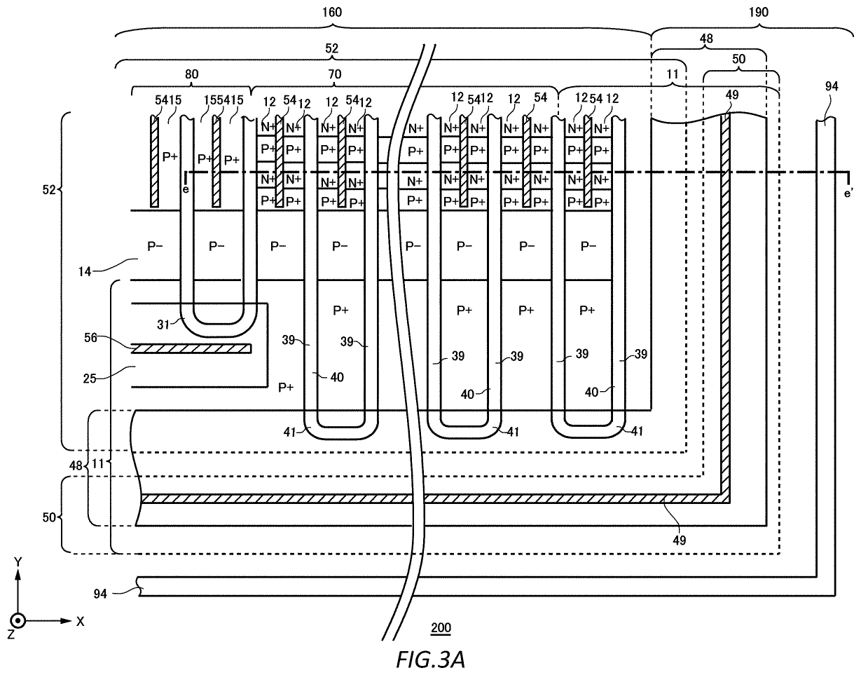

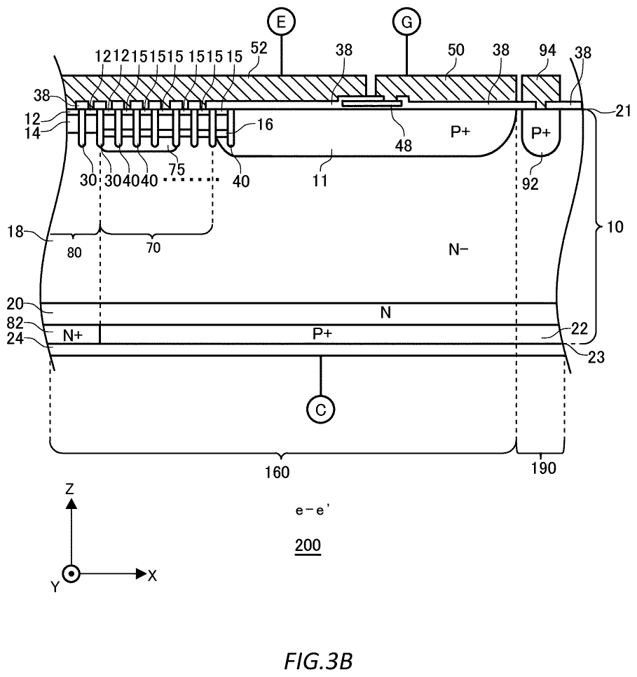

FIG. 3A is an enlarged view representing an example of an upper surface of a semiconductor device 200 according to a comparative example. Similarly as in FIG. 2A, FIG. 3A illustrates the region A illustrated in FIG. 1, that is, the vicinity of the boundary between the active section 160 and the edge termination structure section 190. In the semiconductor device 200, a same reference sign is assigned to a member common to the semiconductor device 100.

The transistor section 70 of the semiconductor device 200 is provided between the diode section 80 in proximity to the edge termination structure section 190, and the edge termination structure section 190 in a top view. That is, as is different from FIG. 2A, the transistor section 70 is arranged on the outermost side of the active section 160. The contact hole 54 is provided above the well region 11. Accordingly, the well region 11 is electrically connected to the emitter electrode 52 which is not illustrated in the drawing.

FIG. 3B illustrates a cross section e-e′ in FIG. 3A. The cross section e-e′ is an XZ plane passing through the emitter region 12, the contact region 15, and the base region 14, and also through the gate trench portion 40 and the dummy trench portion 30.

As described above, in the semiconductor device 200, the transistor section 70 is arranged on the outermost side of the active section 160. In addition, in the edge termination structure section 190, the collector region 22 of a P type is provided on the back surface 23 side of the semiconductor substrate 10. That is, the collector region 22 is continuously provided on the back surface 23 side of the semiconductor substrate 10 over the edge termination structure section 190 from the transistor section 70.

The transistor section 70 of the semiconductor device 200 has the trench bottom portion 75. It is however noted that when the trench bottom portion 75 is provided in the entire transistor section 70 provided on the outermost side of the active section 160, the trench bottom portion 75 contacts the well region 11. Since the well region 11 is electrically connected to the emitter electrode 52, the trench bottom portion 75 is fixed to an emitter potential, and a current can not flow.

Therefore, in the transistor section 70 provided on the outermost side of the active section 160, the trench bottom portion 75 is not provided on the edge termination structure section 190 side. With this configuration, the trench bottom portion 75 is spaced apart from the well region 11 electrically connected to the emitter electrode 52. Accordingly, the semiconductor device 200 has the trench bottom portion 75 smaller than that of the semiconductor device 100, so that a turn-on characteristic falls according to the difference. In addition, a breakdown voltage of the semiconductor device 200 becomes lower than that of the semiconductor device 100, so that a latch-up resistance falls.

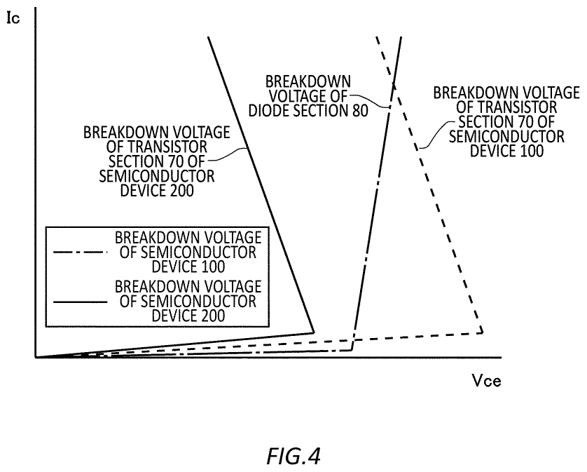

FIG. 4 is a graph representing breakdown voltage waveforms of the semiconductor device 100 and the semiconductor device 200. In general, a breakdown voltage of a device is determined by a breakdown voltage of a trench portion bottom where current crowding tends to occur. Since the IGBT has a negative resistance, as a current Ic increases, a voltage Vce decreases, and current crowding occurs in a same location such as the trench portion bottom. On the other hand, in the FWD, as the current Ic increases, the voltage also increases, so that the current is not to be crowded in a single location.

Since a breakdown voltage of the IGBT is lower than a breakdown voltage of the FWD, a breakdown voltage of an RC-IGBT is determined by a breakdown voltage of the FWD. With regard to the IGBT, because of an influence of an intrinsic parasitic thyristor, when avalanche occurs due to current crowding, there is a risk of latch-up. On the other hand, there is no intrinsic parasitic thyristor in the FWD, even when avalanche occurs due to current crowding, there is no risk of latch-up.

In FIG. 4, a solid line represents the breakdown voltage waveform of the transistor section 70 of the semiconductor device 200, and a chain line represents the breakdown voltage waveform of the diode section 80. In the semiconductor device 200, since the breakdown voltage of the transistor section 70 is lower than the breakdown voltage of the diode section 80, the breakdown voltage of the semiconductor device 200 is determined by the breakdown voltage of the transistor section 70.

On the other hand, the transistor section 70 of the semiconductor device 100 is different from the transistor section 70 of the semiconductor device 200 and is provided in the entire trench bottom portion 75, so that the breakdown voltage rises more than the transistor section 70 of the semiconductor device 200 according to the difference. A broken line represents the breakdown voltage waveform of the transistor section 70 of the semiconductor device 100. The breakdown voltage waveform of the transistor section 70 of the semiconductor device 100 is obtained by moving the breakdown voltage waveform of the transistor section 70 of the semiconductor device 200 in parallel to the right by the rise of the breakdown voltage.

Since the trench bottom portion 75 is not provided in the diode section 80 of the semiconductor device 100, the breakdown voltage of the diode section 80 of the semiconductor device 100 is the same as that of the semiconductor device 200. As illustrated in FIG. 4, in the semiconductor device 100, since the breakdown voltage of the transistor section 70 becomes higher than the breakdown voltage of the diode section 80, the breakdown voltage of the semiconductor device 100 is determined by the breakdown voltage of the diode section 80.

The breakdown voltage waveform of the semiconductor device 100 is in accordance with the chain line of FIG. 4, that is, the breakdown voltage waveform of the diode section 80. On the other hand, the breakdown voltage waveform of the semiconductor device 200 is in accordance with the solid line in FIG. 4, that is, the breakdown voltage waveform of the transistor section 70. In this manner, the breakdown voltage of the semiconductor device 100 becomes higher than the breakdown voltage of the semiconductor device 200, and also in the diode section 80, there is no risk of latch-up even when avalanche occurs, so that the avalanche capability is improved.

While the present invention has been described by way of the embodiments, the technical scope of the present invention is not limited to the above described embodiments. It is apparent to persons skilled in the art that various alterations or improvements can be made to the above described embodiments. It is also apparent from the description of the claims that embodiments added with such alterations or improvements can be included in the technical scope of the present invention.

The operations, procedures, steps, and stages of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10: semiconductor substrate; 11: well region; 12: emitter region; 14: base region; 15: contact region; 16: accumulation region; 17: plug region; 18: drift region; 20: buffer region; 21: front surface; 22: collector region; 23: back surface; 24: collector electrode; 25: connection portion; 29: linear segment; 30: dummy trench portion; 31: edge portion; 32: dummy dielectric film; 34: dummy conductive portion; 38: interlayer dielectric film; 39: linear segment; 40: gate trench portion; 41: edge portion; 42: gate dielectric film; 44: gate conductive portion; 48: gate runner; 49: contact hole; 50: gate metal layer; 52: emitter electrode; 54: contact hole; 56: contact hole; 60: mesa portion; 61: mesa portion; 70: transistor section; 75: trench bottom portion; 80: diode section; 82: cathode region; 92: guard ring; 100: semiconductor device; 102: end side; 160: active section; 190: edge termination structure section; 200: semiconductor device.

What is claimed is:

1. A semiconductor device comprising:
an active section having a transistor section and a diode section; and
an edge termination structure section provided to an outer circumference of the active section, wherein
the transistor section has
a drift region of a first conductivity type which is provided in a semiconductor substrate,
a base region of a second conductivity type which is provided above the drift region,
a trench portion extending from a front surface of the semiconductor substrate to the drift region, and
a trench bottom portion of the second conductivity type which is provided in a lower end of the trench portion, and
the diode section is provided between a transistor section in proximity to the edge termination structure section, and the edge termination structure section in a top view.

2. The semiconductor device according to claim 1, wherein
the trench portion includes a plurality of trench portions, and the transistor section has the plurality of trench portions, and
the trench bottom portion is provided to extend from one to an other of the trench portions which are adjacent to each other.

3. The semiconductor device according to claim 1, further comprising:
a well region of the second conductivity type which is provided in the semiconductor substrate over the edge termination structure section from at least a part of the diode section, wherein
an end of the trench bottom portion in a trench array direction is spaced apart from an end of the well region in the trench array direction in a top view.

4. The semiconductor device according to claim 2, further comprising:
a well region of the second conductivity type which is provided in the semiconductor substrate over the edge termination structure section from at least a part of the diode section, wherein
an end of the trench bottom portion in a trench array direction is spaced apart from an end of the well region in the trench array direction in a top view.

5. The semiconductor device according to claim 1, wherein
the trench bottom portion is electrically floating.

6. The semiconductor device according to claim 2, wherein
the trench bottom portion is electrically floating.

7. The semiconductor device according to claim 1, wherein
a doping concentration of the trench bottom portion is larger than a doping concentration of the drift region, and is smaller than a doping concentration of the base region.

8. The semiconductor device according to claim 2, wherein
a doping concentration of the trench bottom portion is larger than a doping concentration of the drift region, and is smaller than a doping concentration of the base region.

9. The semiconductor device according to claim 7, wherein
the doping concentration of the trench bottom portion is 1E12 cm⁻³ or more and 1E13 cm⁻³ or less.

10. The semiconductor device according to claim 1, wherein
the trench bottom portion is not provided in the diode section.

11. The semiconductor device according to claim 2, wherein
the trench bottom portion is not provided in the diode section.

12. The semiconductor device according to claim 1, further comprising:
a cathode region of the first conductivity type on a back surface side of the semiconductor substrate in the edge termination structure section.

13. The semiconductor device according to claim 2, further comprising:
a cathode region of the first conductivity type on a back surface side of the semiconductor substrate in the edge termination structure section.

14. The semiconductor device according to claim 1, further comprising:
an emitter electrode provided above the semiconductor substrate in the active section; and
a well region of the second conductivity type which is provided in the semiconductor substrate over the edge termination structure section from at least a part of the diode section, wherein
the well region is spaced apart from the emitter electrode in the diode section.

15. The semiconductor device according to claim 2, further comprising:
an emitter electrode provided above the semiconductor substrate in the active section; and
a well region of the second conductivity type which is provided in the semiconductor substrate over the edge termination structure section from at least a part of the diode section, wherein
the well region is spaced apart from the emitter electrode in the diode section.

16. The semiconductor device according to claim 14, further comprising:
an interlayer dielectric film covering the well region in a front surface of the semiconductor substrate, wherein
in the diode section, the interlayer dielectric film further extends inward in the semiconductor substrate by 10 μm or more and 30 μm or less than the well region in a top view.

17. The semiconductor device according to claim 1, wherein
the transistor section further has an accumulation region of the first conductivity type which is provided above the trench bottom portion, and
the accumulation region is not provided in the diode section.

18. The semiconductor device according to claim 2, wherein
the transistor section further has an accumulation region of the first conductivity type which is provided above the trench bottom portion, and
the accumulation region is not provided in the diode section.

19. The semiconductor device according to claim 1, wherein
the transistor section and the diode section further have an accumulation region of the first conductivity type which is provided above the drift region.

20. The semiconductor device according to claim 17, further comprising:
the drift region between the accumulation region and the trench bottom portion.
